(19) United States
(12) Patent Application Publication
(10) Pub. No.: US 2007/0045108 A1
(43) Pub. Date: Mar. 1, 2007

(54) Monolithic sputter target backing plate with integrated cooling passages

(76) Inventor: Richard E. Demaray, Portola Valley, CA (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/497,669

(22) Filed: Aug. 1, 2006

Related U.S. Application Data
(60) Provisional application No. 60/711,893, filed on Aug. 26, 2005.

(51) Int. Cl. C23C 14/00

(52) U.S. Cl. 204/298.12

(57) ABSTRACT

A single-piece backing plate for a sputtering target is disclosed where cooling passages are formed internal to the backing plate. In some embodiments, cooling passages can be formed through the edges of a single plate of material by gun drilling. These passages can then be sealed at the edge so as to form cooling passages within the plate. A sputtering target can then be bonded to one side of the plate to form a target assembly. In some embodiments, an insulating plate can be permanently bonded a side of the backing plate. Some embodiments of the target plate according to the present invention remove the need for multiple internal sealing surfaces, multiple attachment devices, and external back-side plasma suppression plates that are often utilized in conventional backing plate assemblies.

### RELATED APPLICATION

The present application claims priority to Provisional Application No. 60/711,893, filed on Aug. 26, 2005, by Richard E. Demaray, which is herein incorporated by reference in its entirety.

### BACKGROUND

1. Field of the Invention

The present invention is related to a backing plate for utilization in a sputtering apparatus and, more particularly, to a monolithic sputter target backing plate with integrated cooling passages.

2. Discussion of Related Art

In a sputtering deposition apparatus, the target is typically mounted to a backing plate. The backing plate provides both structural integrity and cooling to the target as a whole. Further, the backing plate can provide cathodic electrical coupling to the target material itself. Typically, the backing plate is utilized as a part of the pressure vessel of the deposition chamber and therefore provides both vacuum sealing and structural support to the chamber. As part of the pressure vessel, the backing plate as a whole can be subjected to roughly 1 atmosphere of pressure between inside and outside the pressure vessel.

Current practice is to provide a target backing plate of aluminum, titanium, or copper that has coolant passages machined on the side of the plate opposite the surface used for target bonding. A second plate is fabricated and machined with grooves or other preparations for seals such as o-rings or other cross section polymeric seals around the periphery and also around each fastener. To hold the two plates together against an internal pressure of up to about 60 psi, more than 100 screws can be utilized. Each screw has it's own o-ring seal to prevent leaking. The sensitivity of the two plates to disassembly and cleaning results in the requirement to inspect each plate after cleaning and prior to reassembly. It is also necessary to pressure test every target after target bonding and re-assembly for coolant leakage. Since the cathode is operated at many hundreds of Volts and sometimes more than 10 s of kilowatts, water leaks are a major safety concern. Further, eliminating water leaks represents a significant fraction of the down time of manufactured sputtered production.

FIG. 1 illustrates a conventional backing plate arrangement 100. In order to provide cooling to the target, the backing plate is typically constructed in two halves as is shown in FIG. 1. Backing plate 100 includes a first half 101 and a second half 102. First half 101 includes a first surface 102, which is machined smooth in order to mount a target material 110. Target material 110 can be a continuous monolithic sheet of material to be deposited or may be tiled. First half 101 also includes a second surface 103. Second surface 103 can be machined to create passages for fluid flow through the backing plate. Further, second surface 103 includes tapped holes in order to attach first half 101 to second half 102.

Second half 102 also includes a first surface 105 and a second surface 106. First surface 105 can be machined to create passages for fluid flow that mate with the passages formed in second surface 103 of first half 101, if any. Further, typically O-ring indentations are formed around each of the passages so that each of the passages are sealed when first half 101 is mated with second half 102. Through holes are formed through second half 102 to mate with tapped holes in first half 101. O-ring indentations are further formed around each of the through holes so that the fastening bolts are sealed against the internal pressure from the cooling fluid. Once completed, first half 101 and second half 102 are mated and bolts through second half 102 are tightened down so that O-rings provided in the O-ring indentations seal all of the water passages tight.

Once constructed, backing plate 100 can be utilized in a sputtering apparatus. However, there are several disadvantages to this approach. First, with a large number of bolts to be tightened and a large number of O-ring seals to be made, the likelihood of leaks can be particularly high. The backing plate typically operates in near vacuum and, as discussed above, seals the sputtering chamber against atmosphere. Further, the sputtering apparatus typically operates at high voltage. Therefore, fluid leaks of any form are particularly detrimental to the deposition equipment.

Further, although first half 101 is typically constructed from titanium, the second half 102 is typically constructed from aluminum. In that case, wet electro-corrosion between the two dissimilar metals becomes a great problem. Additionally, structural integrity of backing plate 100 is somewhat compromised due to the number of seals and parts, sometimes resulting in significant bowing in the backing plate. Such bowing can result in cracked targets or uneven plasma generation from the target.

Fabrication of a generic single plate cooling assembly, without a cooling cover has been the object of intense effort from the early 1990s until the present. In particular, for so called “wide area” sputtering, the need for large sputtering equipment has driven the design of the sputtering equipment and components to ever larger, higher aspect, wider area sputter target and sputter target backing plates. Wide area sputtering originated with requirements for stationary coatings of glass sheets having dimensions of about 360 mm by 465 mm up to about 400 mm by 500 mm, which was referred to as the generation II of flat panel display manufacturing equipment in 1992. The present requirements for generation VII and VIII flat panel displays require glass sheets as large as several meters in each direction. U.S. Pat. No. 5,433,835, by the inventor in the present disclosure, describes the many competing requirements for such a sputter target backing plate.

The '835 patent teaches the use of a target backing plate with a cover to hold the cooling fluid. The backing plate and the cover, together, form an assembly capable of both mounting the sputter target, providing the high voltage and current so that the target can act as a cathode in the sputter process as well as the means of cooling so that the heat of sputtering, which is substantially almost all of the sputter energy, can be carried away from the sputter target.

The '835 patent discloses an attempt at eliminating the various seals and connecting screws that are prevalent with conventional backing plates such as that shown in FIG. 1 In that case, the bottom portion of the backing plate is glue bonded to the cover during assembly. However, on mounting a new target onto the backing plate, the cover must be removed. Often, the disassembly and reassembly operation required of the backing plate is not successful.

Therefore, there is a need for a backing plate that prevents leakage and presents better structural characteristics.

### SUMMARY

In accordance with the present invention, a monolithic backing plate is disclosed. The monolithic backing plate includes integrated cooling passages. Such cooling passages can be formed, for example, by gun-drilling through the monolithic backing plate material.

A cooling backing plate for a sputter target according to some embodiments of the present invention include a single metallic plate with a first surface for mounting a sputter target; cooling channels formed laterally within the single metallic plate, the cooling channels being formed through the single metallic plate; and plugs positioned in the cooling channels so as to seal and form cooling passages within the single metallic plate. In some embodiments, the cooling channels are formed through an edge of the single metallic plate. In some embodiments, the cooling channels have a diameter that is greater than ½ a thickness of the single metallic plate. In some embodiments, the single metallic plate is a material from a group consisting of titanium, aluminum, nickel, cobalt, nickel alloy, cobalt alloy, copper, and iron. In some embodiments, the single metallic plate has a lateral width greater than a substrate. In some embodiments, the single metallic plate has a smallest dimension greater than about 15 inches. The single metallic plate can be rectangular, a parallelapiped, oval, circular, triangular, or multi-sided. In some embodiments of the invention, an insulating plate is permanently bonded to a second surface of the single metallic plate opposite the surface where the target is bonded.

A method of forming a cooling backing plate for a sputtering target according to the present invention includes machining a single plate of material to form a smooth, flat first surface for mounting a sputtering target; forming through-holes through the single sheet in directions parallel with the smooth, flat first surface; and positioning plugs within the through holes so as to form that cooling channels are formed within the single sheet of material. In some embodiments, forming through-holes includes gun-drilling holes through an edge of the single plate of material. In some embodiments, forming through-holes includes laser ablation machining through an edge of the single plate of material. In some embodiments, forming through-holes includes electrodischarge machining through an edge of the single plate of material. In some embodiments, the method further includes bonding an insulating plate on a second surface of the single plate of material opposite the first surface of the single plate of material.

A target assembly according to some embodiments of the present invention includes a backing plate, comprising: a single metallic plate; cooling channels formed laterally within the single metallic plate, the cooling channels being formed through the single metallic plate; and plugs positioned in the cooling channels so as to seal and form cooling passages within the single metallic plate; and a sputtering target bonded to a first surface of the backing plate. In some embodiments, the target assembly includes an insulating plate permanently bonded to a second surface of the backing plate, the second surface opposite the first surface.

These and other embodiments are further discussed below with respect to the following figures.

### BRIEF DESCRIPTION OF THE DRAWINGS

FIG. 1 shows an example of a conventional target assembly with a conventional backing plate.

FIGS. 2A and 2B illustrate a target assembly with a monolithic backing plate according to some embodiments of the present invention.

FIG. 3 shows a cross-sectional view of a backing plate according to some embodiments of the present invention.

FIG. 4 illustrates details of cooling passages in cross-sectional views of a backing plate according to some embodiments of the present invention.

FIG. 5 illustrates further details of cooling passages in cross-sectional views of a backing plate according to some embodiments of the present invention.

FIG. 6 shows utilization of a target assembly according to the present invention in a sputtering apparatus.

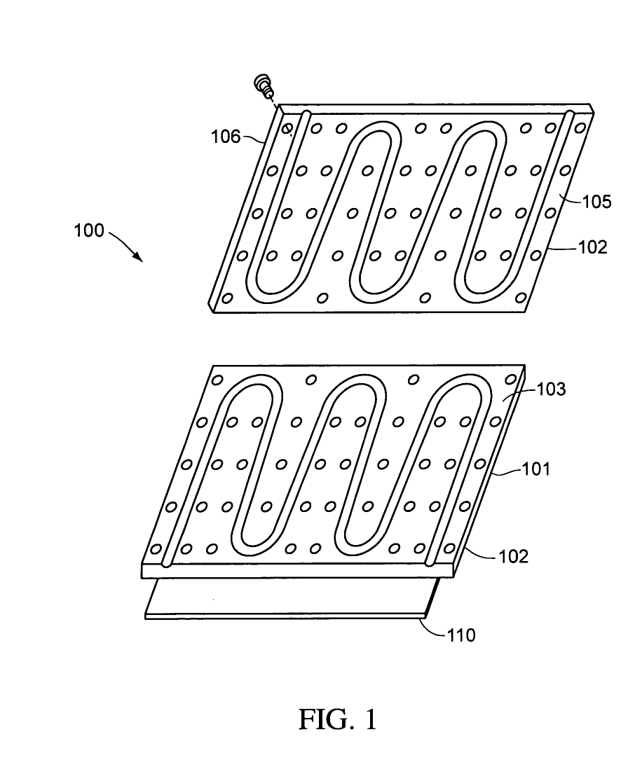

In the figures, elements having the same designation have the same or similar functions.

### DETAILED DESCRIPTION

Embodiments of the present invention provide a backing plate that supports and cools a sputtering target mounted to it in a vacuum chamber. The target, fixed to the backing plate, can be positioned opposite a substrate in the vacuum chamber to be coated. In practice, the target and backing plate are provided with electrical power so as to support a diffuse plasma discharge opposite the sputter target. In the case of so called magnetron sputtering, a magnetic field is provided that propagates through the backing plate and target, supporting a plasma discharge suitable for high rate sputtering.

In accordance with the present invention, a manufacturing method of forming a series of passages in the backing plate is presented. In some embodiments, the series of passages can be fabricated in a single plate of metal such as aluminum, titanium, stainless steel, or other machine-able material. The series of passages can be suitable for passage of a cooling fluid. As a result, a bulky and difficult-to-seal cover plate to hold the cooling fluid in the backing plate is not necessary. Also, the fasteners, seals, and O-rings used to fasten the cover to the target backing plate are eliminated. The single monolithic plate according to the present invention is stronger than conventional backing plates, and leak free after final manufacturing. Additionally, fabricating drilled holes in a single plate of material is also less time consuming and lower cost than machining fully relieved coolant channels in the surface of a single plate.

In some embodiments of the monolithic backing-plate according to the present invention, the time to assemble and test for leakage of the monolithic backing plate is reduced with respect to the conventional backing plate with cover because there are no removable fasteners or seals along the pressurized coolant path. Additionally, without the need for disassembly and reassembly, a monolithic backing plate according to some embodiments of the present invention provides for a lower cost for target bonding to the backing plate itself.

Further, some embodiments of backing plate according to the present invention demonstrate superior bending strength over conventional backing plates. Without backside vacuum, some embodiments of backing-plate according to the present invention bow much less than a conventional backing plate of equivalent total thickness with a cooling plate and a cover. Reduced bowing or bending of the backing plate under the force of atmosphere can, in some embodiments, result in the sputter target being positioned closer to a source of magnetic field in the sputtering apparatus. Such positioning can increase the effective magnetic field at the surface of the sputter target, resulting in a higher sputtering rate at the center of the target. High sputtering rates at the center of the target can provide for improved film uniformity and can also provide for more uniform target erosion and longer target life. Longer sputter target life can translate to lower sputter manufacture cost.

In some applications of a backing plate, a backside vacuum can be applied to improve the target flatness during operation and therefore both the film uniformity and the target life. Some embodiments of a backing plate according to the present invention can include a permanent low cost insulator permanently bonded to the monolithic backing plate on the side opposite that to which a target is mounted. A separate insulating assembly, which is used in conventional backing plates with the cover closed cooling design, to prevent plasma discharge in the low pressure magnet chamber is thusly eliminated. In the conventional design, the separate insulator assembly needs to be provided with pump out ports and is susceptible to plasma discharge failure through the pump out ports, leading to catastrophic failure of the backing plate. An insulator permanently bonded to the backing plate is also lower cost and easier to manufacture than an insulator assembly for use with a conventional two-piece backing plate.

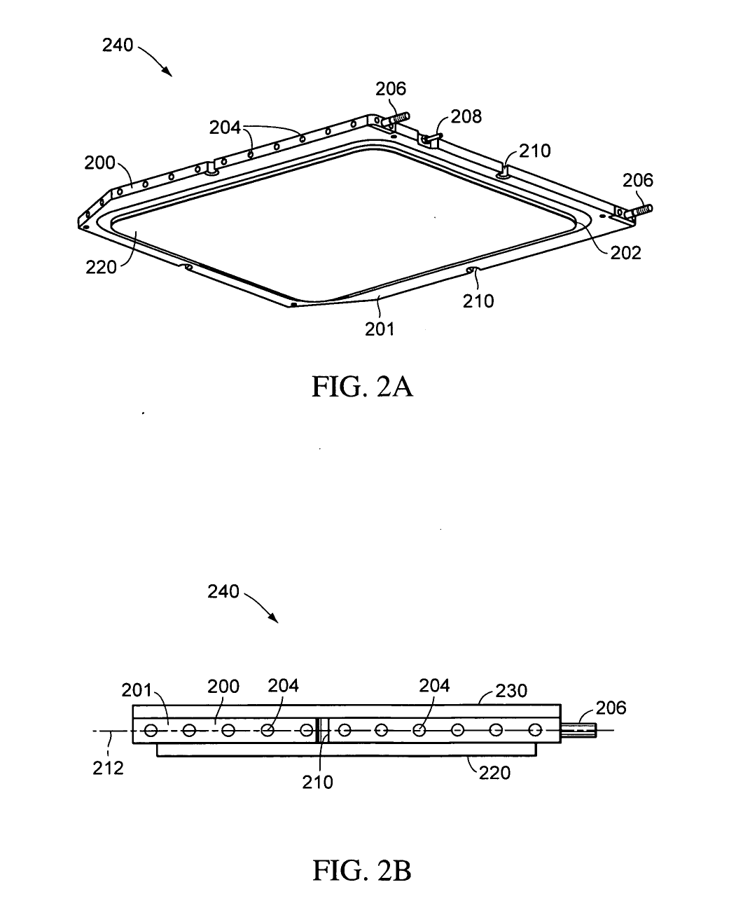

FIG. 2A illustrates a monolithic backing plate 200 according to some embodiments of the present invention. As shown in FIG. 2A, backing plate 200 includes a single plate of material 201. As discussed above, single plate of material 201 can be formed from, for example, aluminum, titanium, stainless steel, or other machine-able material. Plugs 204 shown in FIG. 2A are permanently bonded into cooling passages machined through the center of plate 201. Plugs 204 can be formed of any suitable material, usually made of the same material or other suitable material as that of plate 201. Plugs 204 are then inserted into the formed cooling passages, and screwed, welded, or otherwise bonded into place.

Coolant supply and drain accesses 206 are provided to allow coolant into the cooling passages formed through plate 201. A coolant fluid coupled into one of accesses 206 flows through the cooling passages formed in plate 201 and is drained through the other one of accesses 206.

Alignment notches 210 can be formed around the edge of plate 201 so as to allow for easy placement of backing plate 200 onto a deposition chamber. An O-ring groove 202 is machined into plate 201 so as to seal the deposition chamber once backing plate 200 is properly placed onto the chamber. Electrical pin 208 is provided on the same edge of backing plate 200 as accesses 206. Electrical pin 208 is coupled to an electrical generator to provide power to plate 201 during the deposition process.

As shown in FIG. 2A, a target assembly can be formed with backing plate 200 and target 220. Target 220, which is formed from any target material that is to be deposited onto a substrate in a sputtering chamber, is bonded onto the surface of plate 201 that is configured to the chamber.

With a monolithic, single plate backing plate 200 as shown in FIG. 2A, bonding of targets onto backing plate 200 is fast and simplified. Standard target bonding techniques can be utilized to bond target 220 onto backing plate 200. However, there is no disassembly or reassembly of backing plate 200 that is done in the processes. In addition, the concern of damage to critical water sealing surfaces during bonding of a target is eliminated.

Forming and maintaining a back-side vacuum, a vacuum on the side of a backing plate opposite the side on which the target is bonded, is well understood for wide area sputter targets in general. In utilization with a back-side vacuum a further insulating part has been utilized to form independent vacuum seals about the periphery of the upper vacuum chamber and the backing plate top outer edge. This insulating plate, which can be formed of a high dielectric strength polymer such as polycarbonate or polymer glass laminate such as FR-4, is required in conventional systems to have holes or punctures for pumping out the region between the insulator and the back side of the target assembly. These holes further require dielectric covers to prevent glow discharge and arcing during operation.

FIG. 2B shows a side view of an embodiment of target assembly 240 as shown in FIG. 2A that is suitable for utilization with a back-side vacuum. In the embodiment of backing plate 200 shown in FIG. 2B, an insulating plate 230 is permanently bonded to plate 201 on the surface of plate 201 opposite that on which target 220 is bonded. Backing plate 200 does not have to be disassembled for target bonding to form a target assembly.

In some embodiments, the dielectric or insulating component 230 is permanently attached to the back side of plate 201 with an adhesive. Having a permanently attached insulating component eliminates the separate dielectric insulating sheet and its two o-ring seals as well as the requirement for venting and insulating the vent holes of the dielectric component that is prevalent in conventional target assemblies. Care is taken to avoid the formation of bubbles or voids in the bond between dielectric insulating plate 230 and water cooled plate 201 because bubbles and voids will expand and delaminate during operation with back-side vacuum, potentially leading to mechanical interference with a scanning magnet assembly placed over insulating plate 230 or leading to arcing and plasma damage to the sputtering equipment where target assembly 240 is utilized.

Bonding of dielectric sheet 230 to the titanium, aluminum, or other metal of plate 201 includes chemical cleaning and light garnet bead blasting to roughen the back side surface of backing plate 220. In each choice of particular adhesive, there are industry standards of aircraft or marine grade primer coating for high strength epoxy adhesives which are applied and cured to the metallic surface of the backside (the side opposite that which target 220 is bonded) of backing plate 220. Then, epoxy is applied in an even coating thickness with a minimum thickness at least three times the RMS roughness of the primed metallic surface to a green epoxy thickness uniformity of about 10%. Dielectric sheet 230, which typically has a minimum thickness of about 0.060 inches (where the dielectric strength of dielectric insulating plate 230 is roughly 3 times the peak voltage applied to target assembly 240), is then brought into contact with the primed surface of plate 201. The dielectric plate 230 is bowed so that a line contact between plate 230 and plate 201 can be formed, preventing the formation of bubbles or voids. The radius of curvature of insulator sheet 230 is then increased so that the surfaces come into a void free contact until the whole sheet 230 is in void-free planar contact with plate 201. The combination of plate 201 and plate 230 is then pressed by use of a flat press or placed in a vacuum bag which is evacuated to provide a uniform high pressure. The pressed assembly is then heated for a period consistent with the best practice use of the epoxy or adhesive that is chosen. This, then, creates a permanent bonding between plate 201 and insulating plate 230. Target assembly 240 can then be repeatedly formed by repeated bonding of target 220 to backing plate 200 without the need to disassembling plate 201 from plate 230.

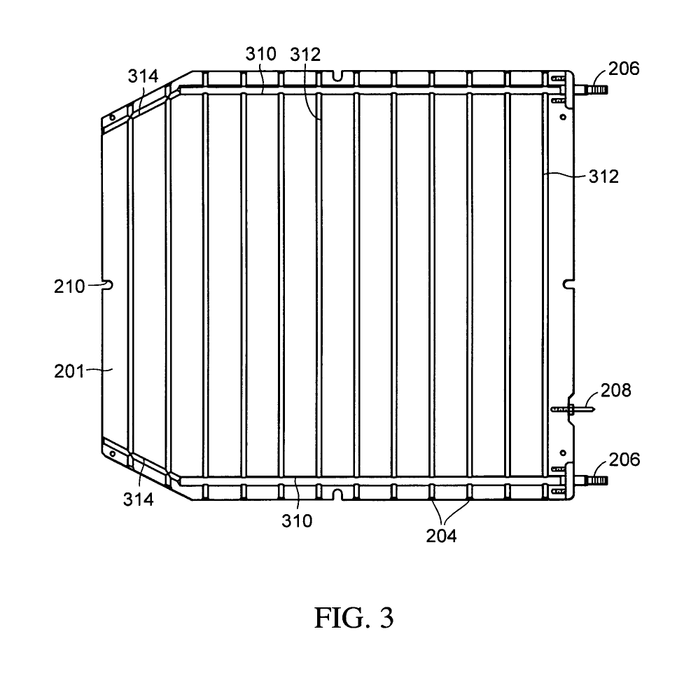

FIG. 3 shows a cross section of plate 201 through line 212 as shown in FIG. 2B. As shown in FIG. 3, plate 201 is edge drilled to form cooling passages throughout the interior of plate 201. In the embodiment shown in FIG. 3, cooling passages 310, 312, and 314 are shown.

Utilizing a gun-drill technique, for example, plate 201 can be edge drilled in any direction through plate 201. In some embodiments, a passage can be formed that is within about 70% of the thickness of plate 201. Other applicable techniques for forming cooling passages 310, 312, or 314 include electro-discharge machining and laser ablation.

In an example that was produced, plate 201 was a titanium plate of about 22 mm thickness and having planer dimensions of about 1043 mm wide by about 1023 mm long. Transverse cooling passages 312 of at least 15.3 (⅝″) mm in diameter were formed. Cooling passages 310, 312, and 314 had diameter that was 69.5% of the thickness of the plate and length of over a meter through plate 201. The number of cooling passages 312, the spacing of cooling passages 310, 312, 314, and their diameters can be easily calculated to support a desired coolant flow at a given inlet pressure so as to provide cooling to target backing plate 200 having a desired thermal capacity by use of well known rules or look up tables, such as those found in, for instance, “Perry's Chemical Engineering Handbook, sixth ed. McGraw Hill Inc. 1984 or similar reference.

As shown in FIG. 3, there were 12 evenly spaced cooling passages 312 with two cooling passages 310 and two cooling passages 314 arranged to provide uniform cooling over plate 201. In general, the diameters of cooling passages 310, 312, and 314 can be the same or different.

The aspect ratio of these cooling passages 310, 312, and 314 to the plate width was about 68. The gun drilling process included clamping titanium plate 201 to a table so as to flatten the plate to within 0.010 inches across its upper surface. A gun drill manufactured by Eldorado Gun Drill, having a usable reach of at least 41 inches and an outer cutting head diameter of ⅝ inches was fitted to a Dotson Horizontal Gun Drilling machine. The drill speed was 500 to 600 RPM for titanium. For aluminum it would have been 4000 rpm or more. For Titanium, the feed rate was about 0.3 inches/minute. For aluminum the feed rate could be in the range of 2 inches/minute or more. For the titanium plate the hydraulic cutting fluid was fed down the Eldorado drill at about 500 psi. For an aluminum plate the cutting fluid would be fed down the drill at 600 psi or more.

In the case of horizontal gun drilling of a wide thin plate, such as plate 201, the condition of the gun drill rod bushing must be very good. Once the drilling process is started, the drilled hole acts as the bushing for the cutting tool so that the machined hole is parallel to the surface of the plate and can continue through the width or length of plate 201 with high precision to prevent broaching the surface of plate 201. In this fashion, cooling accesses 310, 312, and 314 were formed completely through the edges of plate 201. The gun drill was centered to about 10% of the remaining sidewall thickness of 3.2 mm for the longest passages at the opposite edge, or to within 0.3 mm of the center of the plate.

FIG. 3 illustrates a pattern of cooling passages that can be formed. Any other pattern can be formed in the interior of plate 201. Using a gun-drilling technique, any passage following substantially a straight path edgewise through plate 201 can be formed. As shown in FIG. 3, cooling passages 310 form larger diameter passages that are coupled to accesses 206 to carry cooling fluid or cooling gas in and out of backing plate 200. Smaller cross passages 312 are formed substantially perpendicular to passages 310. In general, passages 312 are formed completely through plate 201 in order to facilitate cleaning of the passages after they are formed. As shown in FIG. 3, passages 314 are formed at an angle to cooling passages 310 and couple to the end of cooling passages 310. In general, the spacing of cooling passages 312 can be set to optimize the cooling efficiency of backing plate 200.

As further shown in FIG. 3, after passages 312 and 314 are formed and the resulting cooling passages are cleaned of all detritus involved in the machining process (e.g., shavings, cutting fluids, etc.), accesses 206 are inserted and sealed with cooling passages 310.

Further, all cooling passages 312 and 314 are plugged by insertion of plugs 204. Plugs 204 are permanently bonded into passages 312 and 314. In some embodiments, plugs 204 are formed titanium plugs that are welded into passages 312 and 314.

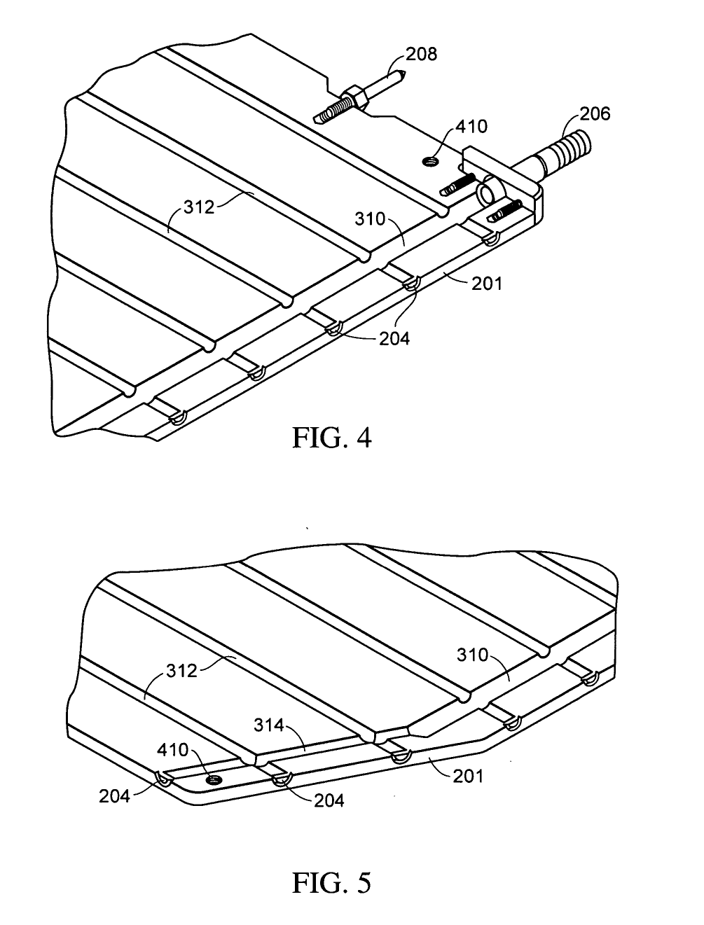

FIGS. 4 and 5 illustrate more details of cooling passages 310, 312, and 314. As shown in FIG. 4, cooling passages 312 pass through cooling passages 310 and are plugged at the edge of plate 201 with plugs 204. As shown, electrical pin 208 can include a screw that is received in a tapped hole in plate 201. Further, access 206 can be inserted into cooling access 310, sealed, and fastened in place utilizing screws and tapped holes in plate 201.

FIG. 5 illustrates cooling passages 314. In the embodiment of backing plate 201 illustrated in FIG. 5, the plate includes a beveled section such that cooling passage 310 is not formed completely through plate 201. Instead, a second passage 314 is formed from the opposite edge to join with cooling passage 310. Again, cooling passages 312 are formed substantially perpendicular to cooling passage 310 and in such a way as to pass through either cooling passage 310 or cooling passage 314. Again, cooling passages 312 and cooling passages 314 are sealed with plugs 204.

Although the embodiment of backing plate 200 illustrated in FIGS. 2A-5 are substantially rectangular with one end of the rectangle being beveled, backing plate 200 can be of any planar shape, including circular, elliptical, triangular, or other polygonal or parallelepiped shape.

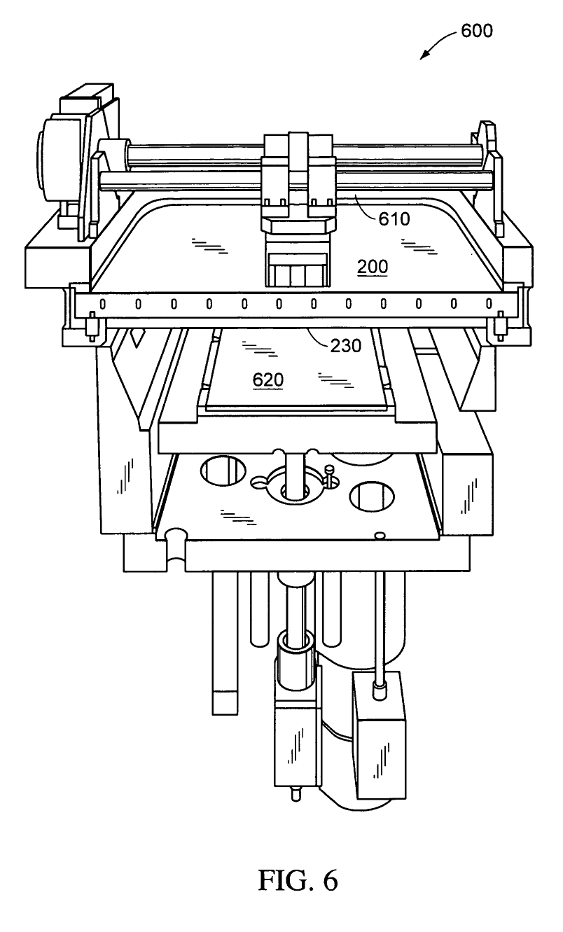

FIGS. 6 illustrates utilization of an embodiment of a backing plate 200 according to the present invention in a sputtering chamber 600. Backing plate 200 is fixed in a location beneath a magnet assembly 610, which provides a magnetic field through backing plate 200 to target 230. Target 230 is bonded to backing plate 200 in such a fashion that it is opposite a substrate 620 when backing plate 200 is positioned in chamber 600. During deposition, the volume between backing plate 200 and substrate 620 is evacuated and provided with a sufficient sputter gas in a pressure range of a few millitorr. Further, a backside vacuum may be formed on the top of backing plate 200 where magnet assembly 610 is located.

Embodiments of backing plates according to the present invention have internal cooling passages and therefore do not require fasteners or seals to air or vacuum. Further, the single plate structure of backing plate is structurally sound to support the weight of atmosphere. In some embodiments, a back side vacuum may be created to reduce bowing of the backing plate even further. In that case, an integrated dielectric shield (insulating plate) can be permanently bonded to the single metallic plate of a backing plate to prevent plasma on the back side of the target assembly. In both cases, the integrated assembly allows for superior film uniformity and prevents target or target tile bending and breakage, which is critical for dielectric and composite target performance. Further, the predictable and repeatable planar positioning between the target, the incident magnetic field intensity, and the substrate results in improved film uniformity and target utilization.

In operation, the planarity of the target in a target assembly according to the present invention, even without backside vacuum is much improved. Further, backside vacuum with embodiments that include a permanently bonded insulating plate can be applied without the need for additional precautions for backside plasma prevention. The planarity of the target assembly during target bonding, as well as during operation, allows for close setting of tiles because it prevents the target tiles from contacting neighboring tiles due to target bowing. Edge-to-edge point contact is the most common form of tiled target failure and is observed in both air and vacuum backside operation utilizing conventional backing plates.

Some embodiments of the present invention also allow for failure and also sputter formation from the backing plate material due to large gaps in the placement of the tiles. Due to the planarity of the backing plate assembly, tiles can be set closer together and operated without tile edge contact and cracking which leads to particles and early target replacement. This is very critical for brittle target material such as ITO, LiPON, LiCoO₂, other oxide or dielectric compounds, and hot and cold pressure formed composite materials such as aluminum silicon and rare earth doped compounds such as oxides and metals.

A sputter target 220 with a thickness of about 4 mm was bonded to the particular example of backing plate 200 described above (i.e., a 22 mm thick approximately 1 m² plate) by soldering. In some cases, targets can be bonded by conductive epoxy bonding as well. The resulting target assembly 240 was suitable for mounting on a vacuum chamber as shown in FIG. 6. Target 222 was about 889.3 mm long and about 770 mm wide.

The backing plate of similar dimensions with cover to hold cooling fluid as described in the '835 plate deflects under vacuum with a deflection of up to 3 mm. During operation, that two-plate assembly takes on a permanent deflection of at least 1.3 mm. The total deflection, therefore, without application of backside vacuum is about 4.3 mm. The target is about 22 mm thick and the magnet fly height is at least 1 mm from the backside of the backing plate. With a 4 mm sputter target thickness, the total distance from the face of the magnetic assembly at air is 27 mm. In operation, and without backside vacuum, the deflection of 4.3 mm experienced by the conventional target assembly is 16% of the distance to the magnet. It is well known that the magnetic field falls off faster than the inverse of the distance. Because the magnetron sputter rate is proportional to the magnetic field strength at the surface of the target, such a large change in the magnetic field center to edge of the target leads to large sputter rate and film thickness non-uniformity greater than 16% center-to-edge of the substrate coating. Because the standard industry uniformity is 5%, significant engineering must go into re-engineering such equipment to meet industrial standards.

In the example of target assembly 240 described above (i.e., a 22 mm thick approximately 1 m² plate), a resistance to permanent deflection is observed and, in operation without backside vacuum, a deflection of about 1.3 mm is observed. This low deflection leads to a spacing difference, center to edge of the target backing plate assembly 240 of about 4.8%, which complies with industry standards for sputter rate and film thickness uniformity.

In the case where back side vacuum is utilized, the issue of target bowing is remedied. The issue of insulating the backside of the target assembly from glow discharge and arcing is mitigated with permanently bonded insulating plate 230. In addition, target removal and cleaning of the backing plate as well as rebonding benefit from the elimination of 100 or more o-rings and screws as utilized in conventional target assemblies. Without the many seals and screws, leaking during operation, which has a catastrophic effect on the high voltage operation of the equipment, is eliminated. Assembly and disassembly of the cover to hold the cooling fluid and post assembly pressure testing are eliminated with the single plate monolithic backing plate. And lastly, electrolytic corrosion due to the use of different metals for the backing plate and the cover is eliminated by the use of a single metal for the monolithic backing plate.

In addition, phase change cooling can be accomplished with embodiments of the present invention due to the structural property. Liquid can be supplied to the internal passages of the backing plate so that an orifice is provided within one of the cooling tubes. The liquid undergoes a phase change from liquid to gas within the backing plate. Each passage can be treated with such an expansion so that cooling is brought about in each tube. A conductive material such as copper or aluminum is suitable so that the cooling can be conducted uniformly to throughout the backing plate and transferred from the backing plate to the sputter target.

The examples and embodiments of the invention described above are not intended to be limiting. One skilled in the art can utilize this disclosure to develop alternative embodiments that are intended to be within the scope and spirit of the present invention. As such, the invention is limited only by the following claims.

What is claimed is:

1. A cooling backing plate for a sputter target, comprising:
a single metallic plate with a first surface for mounting a sputter target;
cooling channels formed laterally within the single metallic plate, the cooling channels being formed through the single metallic plate; and
plugs positioned in the cooling channels so as to seal and form cooling passages within the single metallic plate.

2. The backing plate of claim 1, wherein the cooling channels are formed through an edge of the single metallic plate.

3. The backing plate of claim 1, wherein the cooling channels have a diameter that is greater than ½ a thickness of the single metallic plate.

4. The backing plate of claim 1, wherein the single metallic plate is a material from a group consisting of titanium, aluminum, nickel, cobalt, nickel alloy, cobalt alloy, copper, and iron.

5. The backing plate of claim 1, wherein the single metallic plate having a lateral width greater than a substrate.

6. The backing plate of claim 1, wherein the single metallic plate has a smallest dimension greater than about 15 inches.

7. The backing plate of claim 1, wherein the single metallic plate is substantially rectangular.

8. The backing plate of claim 1, wherein the single metallic plate is a parallelapiped.

9. The backing plate of claim 1, wherein the single metallic plate is oval.

10. The backing plate of claim 1, wherein the single metallic plate is circular.

11. The backing plate of claim 1, wherein the single metallic plate is triangular.

12. The backing plate of claim 1, wherein the single metallic plate is multi-sided.

13. The backing plate of claim 1 wherein an insulating plate is permanently bonded to a second surface of the single metallic plate

14. A method of forming a cooling backing plate for a sputtering target, comprising:
machining a single plate of material to form a smooth, flat first surface for mounting a sputtering target;
forming through-holes through the single sheet in directions parallel with the smooth, flat first surface; and
positioning plugs within the through holes so as to form that cooling channels are formed within the single sheet of material.

15. The method of claim 14, wherein forming through-holes includes gun-drilling holes through an edge of the single plate of material.

16. The method of claim 14, wherein forming through-holes includes laser ablation machining through an edge of the single plate of material.

17. The method of claim 14, wherein forming through-holes includes electrodischarge machining through an edge of the single plate of material.

18. The method of claim 14, further including bonding an insulating plate on a second surface of the single plate of material opposite the first surface of the single plate of material.

19. A target assembly, comprising:
a backing plate, comprising:
a single metallic plate;
cooling channels formed laterally within the single metallic plate, the cooling channels being formed through the single metallic plate; and
plugs positioned in the cooling channels so as to seal and form cooling passages within the single metallic plate; and
a sputtering target bonded to a first surface of the backing plate.

20. The target assembly of claim 19, further including an insulating plate permanently bonded to a second surface of the backing plate, the second surface opposite the first surface.
